(19) United States
(12) Patent Application Publication
(10) Pub. No.: US 2005/0095744 A1
(43) Pub. Date: May 5, 2005

(54) System to couple integrated circuit die to substrate

(76) Inventor: Song-Hua Shi, Phoenix, AZ (US)

Correspondence Address: BUCKLEY, MASCHOFF, TALWALKAR LLC, 5 ELM STREET, NEW CANAAN, CT, 06840, US

(21) Appl. No.: 10/689,010

(22) Filed: Oct. 20, 2003

(51) Int. Cl. H01L 21/48

(52) U.S. Cl. 438/106

(57) ABSTRACT

A system may include placement of an integrated circuit die on a substrate using a first head, the integrated circuit die including a first plurality of electrical contacts and the substrate including a second plurality of electrical contacts, and application of energy to the integrated circuit die using a second head to form an integral electrical connection between one of first plurality of electrical contacts and one of the second plurality of electrical contacts.

### CROSS-REFERENCE TO RELATED APPLICATIONS

The present application is related to commonly-assigned and co-pending U.S. patent application Ser. No. ______ (Attorney Docket No. P12099), entitled ELECTRONIC ASSEMBLY WITH FILLED NO-FLOW UNDERFILL AND METHODS OF MANUFACTURE and filed on and U.S. patent application Ser. No. ______ (Attorney Docket No. P15835), entitled TEMPERATURE SUSTAINING FLIP CHIP ASSEMBLY PROCESS and filed on ______.

### BACKGROUND

An integrated circuit (IC) die may include electrical devices that are integrated with a semiconductor substrate. The IC die may also include conductive paths that electrically couple the electrical devices to one another and to external connections. The die may include several layers of conductive paths, with each layer separated from adjacent layers by an inter-layer dielectric (ILD). A material having an extremely low dielectric constant (k) is often selected for the ILD in order to minimize capacitance coupling and crosstalk between the conductive paths.

Low-k ILD materials often exhibit a coefficient of thermal expansion (CTE) that differs significantly from other elements to which they are coupled, such as the other elements of an IC die and an IC package. Moreover, low-k ILD materials are often brittle. These two characteristics may cause low-k ILD materials to crack during IC die fabrication and/or operation.

### BRIEF DESCRIPTION OF THE DRAWINGS

FIG. 1 is a bottom view of an IC die according to some embodiments.

FIG. 2 is a top view of an IC package according to some embodiments.

FIG. 3 is diagram of a process according to some embodiments.

FIG. 4 is a side elevation of a system according to some embodiments.

FIG. 5 is diagram of a process according to some embodiments.

FIG. 6 is a side elevation of a substrate according to some embodiments.

FIG. 7 is a side elevation of a substrate after underfill material has been placed thereon according to some embodiments.

FIG. 8 is a side elevation of a substrate and underfill material after an IC die has been placed thereon by a placement head according to some embodiments.

FIG. 9 is a side elevation of two substrate after two IC dies have been respectively coupled thereto by respective bonding heads according to some embodiments.

FIG. 10 depicts an assembly flow of a system according to some embodiments.

FIG. 11 is a diagram of a system according to some embodiments.

### DETAILED DESCRIPTION

According to some embodiments, a system may include placement of an integrated circuit die on a substrate using a first head. The integrated circuit die may include a first plurality of electrical contacts and the substrate may include a second plurality of electrical contacts. The system may also include the application of energy to the integrated circuit die using a second head to form an integral electrical connection between one of first plurality of electrical contacts and one of the second plurality of electrical contacts. Such a system might reduce ILD mechanical failures and/or provide high fabrication throughput.

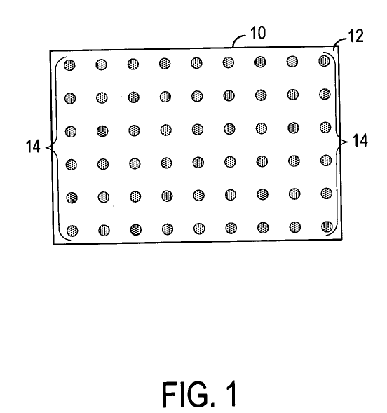

FIG. 1 illustrates IC die 10 according to some embodiments. IC die 10 includes integrated electrical devices and may be fabricated using any suitable substrate material and fabrication techniques. IC die 10 may provide one or more functions. In some embodiments, IC die 10 comprises a microprocessor chip having a silicon substrate.

Side 12 of IC die 10 includes electrical contacts 14. IC die 10 may comprise a flip chip arrangement in which electrical devices that are integrated therein reside between a substrate of IC die 10 and electrical contacts 14. In some embodiments, the substrate resides between the electrical devices and electrical contacts 14.

Electrical contacts 14 may comprise gold and/or nickel-plated copper contacts fabricated upon IC die 10. Electrical contacts 14 may comprise Controlled Collapse Chip Connect (C4) solder bumps. In this regard, conductive contacts 14 may be recessed under, flush with, or extending above first side 12 of IC die 10. Electrical contacts 14 may be electrically coupled to the electrical devices that are integrated into IC die 10.

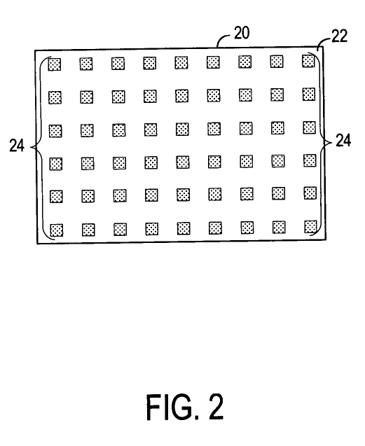

FIG. 2 is a view of a side of substrate 20 according to some embodiments. Substrate 20 may comprise an IC package, a circuit board, or other substrate. Substrate 20 may therefore comprise any ceramic, organic, and/or other suitable material. Substrate 20 may be used to carry power and/or I/O signals between IC die 10 and external electrical components. Substrate 20 may also be used to transmit and receive signals directly to and from IC die 10 according to some embodiments.

First side 22 of substrate 20 includes electrical contacts 24. Electrical contacts 24 may comprise C4 solder bumps or plated copper contacts. Electrical contacts 24 may be recessed under, flush with, or extending above first side 22 of substrate. Although the embodiments of FIGS. 1 and 2 show electrical contacts 14 and 24 as having substantially square or circular cross section, respectively, in other embodiments one or more of electrical contacts 14 and 24 have cross sections of different and/or varying shapes.

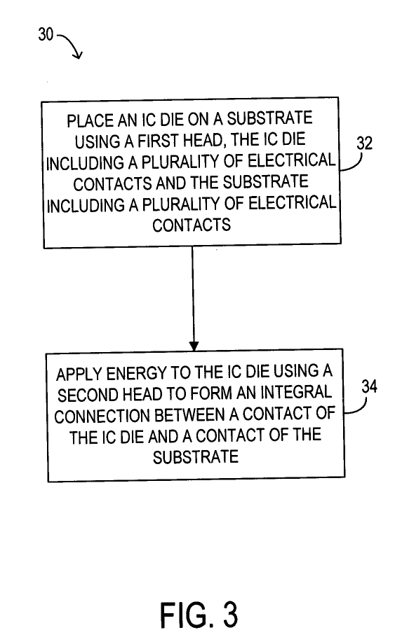

FIG. 3 is a diagram of process 30 according to some embodiments. Process 30 may be executed by one or more fabrication devices, and all or a part of process 30 may be executed manually. Process 30 may be executed soon after fabrication of IC die 10 or may be executed significantly later. An example of the latter scenario may occur if a first company fabricates IC die 10 and substrate 20, and if a second company performs process 30.

Briefly, IC die 10 is placed on substrate 20 at 32 using a placement head. Next, at 34, energy is applied to IC die 10 using a bonding head to form an integral connection between at least one of contacts 14 and at least one of contacts 24. A placement head and a bonding head according to some embodiments will be described in detail below.

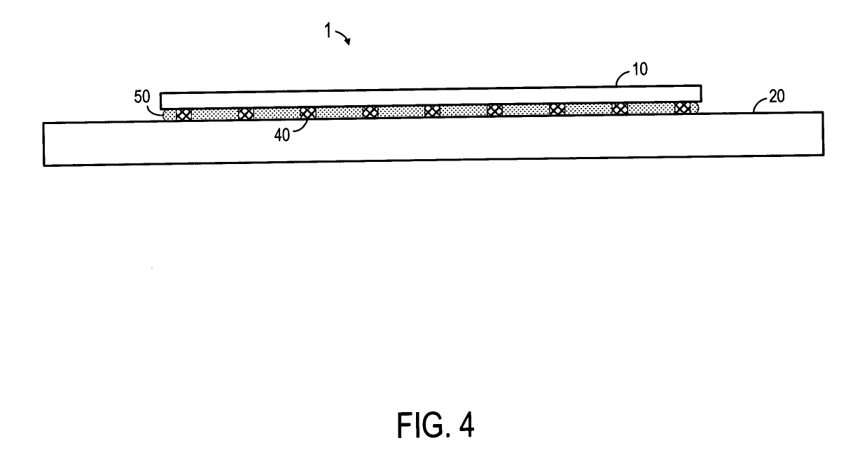

FIG. 4 is a side elevation of system 1 fabricated according to process 30. System 1 includes IC die 10 and substrate 20. Several integral electrical connections 40 have been formed between electrical contacts 14 and electrical contacts 24. FIG. 4 also illustrates underfill material 50, which encapsulates electrical connections 40 and may therefore protect connections 40 from exposure to environmental hazards. Moreover, the CTE of IC die 10 may differ from the CTE of substrate 20 so as to cause undue stress on electrical connections 40 when heated. Underfill material 50 may address this mismatch by distributing the stress away from connections 40.

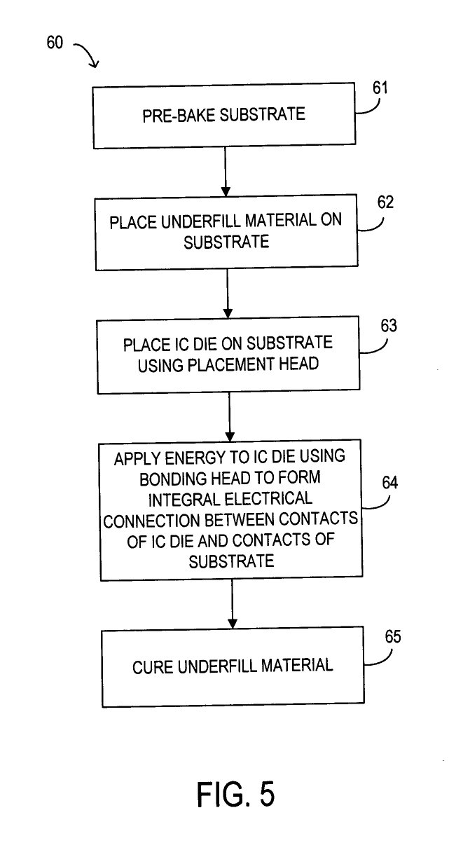

FIG. 5 is a diagram of process 60 to fabricate system 1 according to some embodiments. Process 60 may be executed manually and/or by one or more fabrication devices. Process 60 may be executed by an entity different from the entity or entities responsible for fabricating IC die 10 and substrate 20.

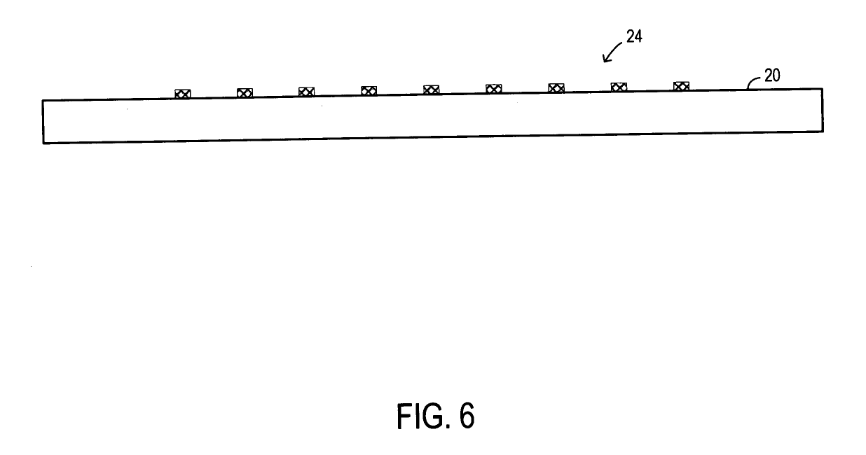

Substrate 20 is pre-baked at 61. Pre-baking substrate 20 may include placing substrate 20 in a pre-bake oven such as a batch oven or an in-line oven that is heated to 160° C. Any suitable pre-baking temperature and/or temperature profile may be used at 61. Pre-baking is intended to remove moisture from side 22 and electrical contacts 24 of substrate 20. FIG. 6 is a side elevational view of substrate 20 and electrical contacts 24 during pre-baking. Pre-baking is not performed in some embodiments.

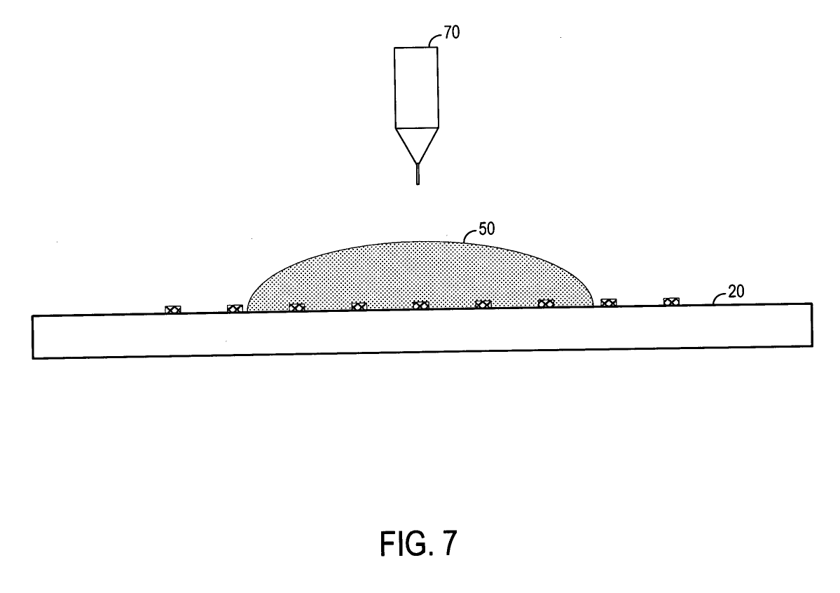

Underfill material 50 is placed on substrate 20 at 62. FIG. 7 illustrates substrate 20 after underfill material 50 has been placed thereon by dispensing device 70. A position and volume of underfill 50 may be determined so as to result in the arrangement shown in FIG. 4 after compression and curing thereof. Dispensing device 70 may comprise any currently- or hereafter-known suitable system, including a linear pump and a positive rotary displacement pump. Some suitable dispensing devices provide heating of underfill 50 and/or substrate 20 prior to, during, and/or after 62.

Underfill material 50 may comprise no-flow underfill material. No-flow underfill material may comprise low-viscosity, thermally-polymerizable, liquid resin systems that may or may not include fluxing additives. Non-exhaustive examples include 50% by weight silica-filled underfill material and STAYCHIP™ DP-0115 by Cookson Electronics-Semiconductor Products. The fluxing additives may deoxidize the metal surfaces of electrical contacts 24 and electrical contacts 14 of IC die 10 during the formation of integral electrical connections 40 therebetween. In some embodiments, underfill material 50 does not include fluxing additives and flux is placed on electrical contacts 24 prior to 62. In some embodiments, flux is also or alternatively placed on electrical contacts 14 prior to 63. Again, underfill material 50 used in some of these embodiments might not include fluxing additives.

IC die 10 is placed on substrate 20 at 63. According to some embodiments, IC die 10 is placed on substrate 20 using a placement head of a pick-and-place machine. Such a machine may align electrical contacts 14 with respective ones of electrical contacts 24 prior to placing IC die 10 on substrate 20. A machine including a placement head according to some embodiments may also provide one or more of substrate pre-heating, substrate support, die side heating, and upgraded placement force.

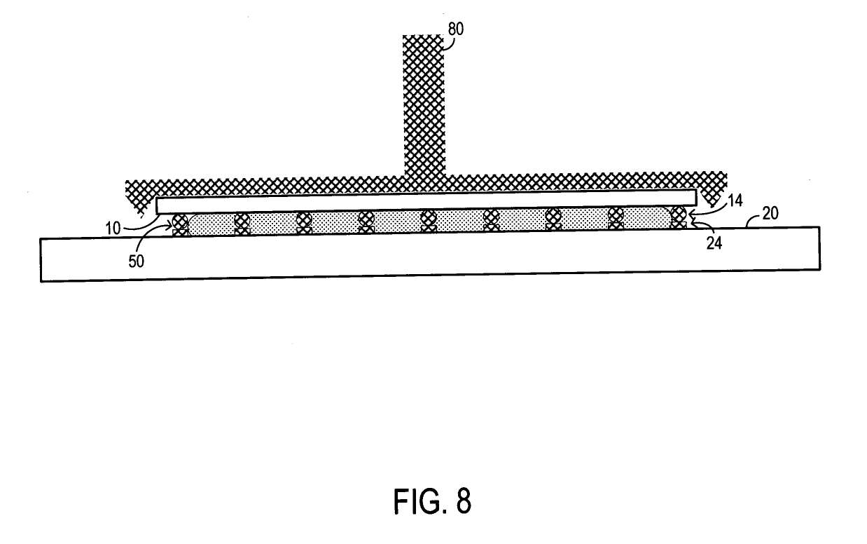

FIG. 8 illustrates substrate 20 after placement of IC die 10 thereon at 63. As shown, IC die 10 may be placed on underfill material 50 so as to position a plurality of electrical contacts 14 directly over respective ones of electrical contacts 24. The plurality of electrical contacts 24 may therefore contact the respective ones of electrical contacts 14 after 63. FIG. 8 also shows that underfill material 50 has been compressed by the weight of die 10 and/or by pressure applied by placement head 80. Any suitable design of placement head 80 may be utilized; embodiments are not limited to the design illustrated in FIG. 8.

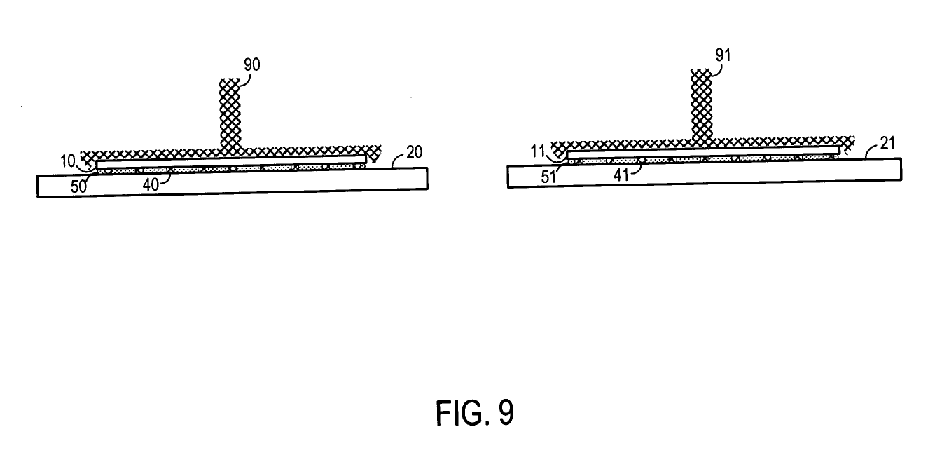

At 64, energy is applied to IC die 10 in order to form an integral electrical connection between at least one of electrical contacts 14 and respective ones of electrical contacts 24. The energy may be applied using a bonding head such as bonding heads 90 and 91 of FIG. 9. As shown, portions of electrical contacts 14 and respective ones of electrical contacts 24 have formed into integral connections 40 and 41 after 64. FIG. 9 illustrates a system in which multiple bonding heads may operate substantially simultaneously.

The configurations of bonding heads 90 and 91 may be different from or identical to one another, and either or both may differ from the illustrated configuration. Either or both of bonding heads 90 and 91 may comprise a thermocompression bonder that applies energy to a die by applying a force to bias the die toward a respective substrate 20 and/or by applying thermal energy to the die. Other types of bonding may be used according to some embodiments, including ultrasonic bonding.

Next, at 65, underfill material 50 is cured to form an inert protective polymer. Underfill material 50 may be cured by heating substrate 20 in an in-line zone oven or an off-line batch oven. The temperature to which substrate 20 is heated may be lower than the temperature required to reflow connections 40. An in-line oven may be used immediately after 64 to quickly reduce any ILD stress within IC die 10. Thereafter, curing may be completed using an off-line oven. System 1 of FIG. 3 illustrates the results of process 60 according to some embodiments.

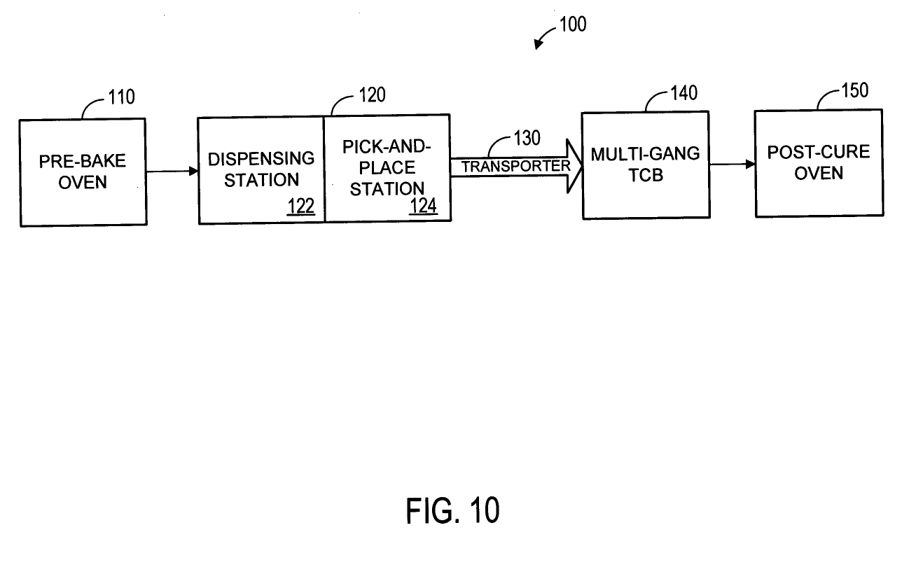

FIG. 10 depicts an assembly flow of system 100 according to some embodiments. The various elements of system 100 may be combined in one or more composite machines, and the functions of one element may be allocated to one or more other machines. Moreover, each element of system 100 may be located at a single manufacturing plant or one or more elements may be located at one or more manufacturing plants.

In some embodiments, substrate 20 is pre-baked in pre-bake oven 110. Pre-bake oven 110 may comprise a Blue-M oven or a Tiros oven. Dispensing station 122 of machine 120 dispenses underfill material 50, and a placement head of pick-and-place station 124 places IC die 10 is on substrate 20. Transporter 130 may comprise a conveyer belt, a robot arm, or any other system to transport substrate 20 from machine 120 to multi-gang thermocompression bonder 140 so as to minimize misalignment of electrical contacts 14 and 24. Multi-gang thermocompression bonder 140 includes two or more bonding heads for forming integral electrical connections between electrical contacts of multiple IC dies and respective electrical contacts of multiple substrates. Underfill material 50 is thereafter cured in post-cure oven 150, which may comprise a Blue-M oven or a Tiros oven.

In some embodiments, pick-and-place station 124 includes two placement heads, and each placement head requires six seconds to properly place an IC die on a substrate. Moreover, multi-gang thermocompression bonder 140 may comprise four bonding heads, with each bonding head requiring twelve seconds per bonding cycle. As a result, elements 124 and 140 may support a throughput of twelve hundred units per hour.

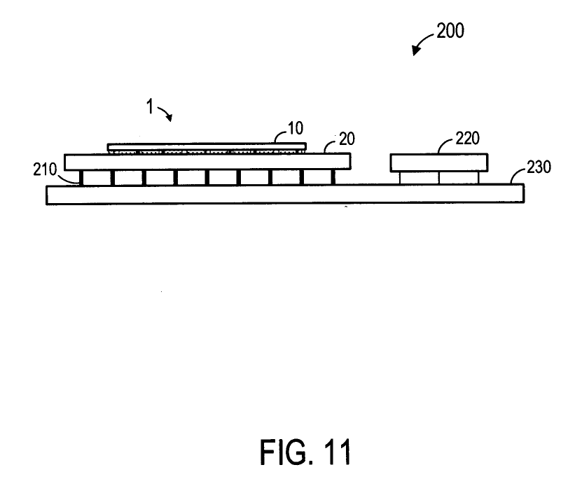

FIG. 11 is a side elevation of system 200 according to some embodiments. System 200 may comprise components of a server platform. System 200 includes system 1 as described above, memory 220 and motherboard 230. System 1 of system 200 may comprise a microprocessor.

Substrate 20 of system 1 may comprise an IC package having through-hole pins 210 that are electrically coupled to electrical contacts 24. Accordingly, pins 210 may carry signals such as power and I/O signals between IC die 10 and external devices. Pins 210 may be mounted directly on motherboard 230 or onto a socket (not shown) that is in turn mounted directly to motherboard 230. Motherboard 230 may comprise a memory bus (not shown) that is electrically coupled to pins 210 and to memory 220. Motherboard 230 may therefore electrically couple memory 220 to IC die 10. Memory 220 may comprise any type of memory for storing data, such as a Single Data Rate Random Access Memory, a Double Data Rate Random Access Memory, or a Programmable Read Only Memory.

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

1. A method comprising:
placing of an integrated circuit die on a substrate using a first head, the integrated circuit die comprising a first plurality of electrical contacts and the substrate comprising a second plurality of electrical contacts; and
applying energy to the integrated circuit die using a second head to form an integral electrical connection between one of first plurality of electrical contacts and one of the second plurality of electrical contacts.

2. A method according to claim 1, further comprising:
placing underfill material on the substrate, wherein placing the integrated circuit die on the substrate comprises placing the integrated circuit die on the underfill material.

3. A method according to claim 2, wherein placing the integrated circuit die on the substrate further comprises:
compressing the underfill material with the integrated circuit die.

4. A method according to claim 3, further comprising:
applying energy to the underfill material to cure the underfill material.

5. A method according to claim 1, wherein placing the integrated circuit die on the substrate comprises:
aligning the first plurality of electrical contacts with the second plurality of electrical contacts.

6. A method according to claim 1, wherein applying energy to the integrated circuit die comprises:
applying a force to the integrated circuit die to bias the integrated circuit die toward the substrate using the second head.

7. A method according to claim 6, wherein applying the energy further comprises:
applying thermal energy to the integrated circuit die using the second head.

8. A system comprising:
a placement head to place an integrated circuit die on a substrate, the integrated circuit die comprising a first plurality of electrical contacts and the substrate comprising a second plurality of electrical contacts; and
a bonding head to apply energy to the integrated circuit die to form an integral electrical connection between one of first plurality of electrical contacts and one of the second plurality of electrical contacts.

9. A system according to claim 8, further comprising:
a dispensing device to dispense underfill material on the substrate,
wherein the placement head is to place the integrated circuit die on the underfill material.

10. A system according to claim 9, wherein the placement head is to apply a force to the integrated circuit die to compress the underfill material with the integrated circuit die.

11. A system according to claim 10, further comprising:
an oven to apply energy to the underfill material to cure the underfill material.

12. A system according to claim 8, the placement head to align the first plurality of electrical contacts with the second plurality of electrical contacts.

13. A system according to claim 8, the bonding head to simultaneously apply thermeal energy and a force to the integrated circuit die, the force to bias the integrated circuit die toward the substrate.

14. A system according to claim 8, further comprising:
a transporter to transport the integrated circuit die from the placement head to the bonding head.

15. A system according to claim 8, further comprising:
a second placement head; and
a plurality of other bonding heads.

16. A system comprising:
an integrated circuit die comprising a first plurality of electrical contacts; and
a substrate comprising a second plurality of electrical contacts,
the integrated circuit die placed on the substrate by a placement head, and an integral electrical connection formed between one of first plurality of electrical contacts and one of the second plurality of electrical contacts by energy applied to the integrated circuit die by a bonding head.

17. A system according to claim 16, the first plurality of electrical contacts aligned with the second plurality of electrical contacts by the placement head.

18. A system according to claim 16, the integrated circuit die to have simultaneously received thermal energy and a force from the bonding head, the force to bias the integrated circuit die toward the substrate.

19. A system comprising:
a microprocessor comprising:
an integrated circuit die comprising a first plurality of electrical contacts; and
a substrate comprising a second plurality of electrical contacts,
the integrated circuit die placed on the substrate by a placement head, and an integral electrical connection formed between one of first plurality of electrical contacts and one of the second plurality of electrical contacts by energy applied to the integrated circuit die by a bonding head; and
a double data rate memory coupled to the microprocessor.

20. A system according to claim 19, the first plurality of electrical contacts aligned with the second plurality of electrical contacts by the placement head.

21. A system according to claim 19, the integrated circuit die to have simultaneously received thermal energy and a force from the bonding head, the force to bias the integrated circuit die toward the substrate.
